(19) United States
(12) Patent Application Publication
(10) Pub. No.: US 2021/0259409 A1
(43) Pub. Date: Aug. 26, 2021

(54) CRUSH-RESISTING STRUCTURE AND CABINET USING THE SAME

(71) Applicant: HONGFUJIN PRECISION ELECTRONICS(TIANJIN)CO.,LTD., Tianjin (CN)

(72) Inventors: HSUEH-CHIN LU, New Taipei (TW); KUO-CHIH HUNG, New Taipei (TW); CHIH-FENG CHANG, Tu-Cheng (TW); HAO-WEN CHENG, Neihu (TW)

(21) Appl. No.: 16/815,163

(22) Filed: Mar. 11, 2020

(30) Foreign Application Priority Data
Feb. 20, 2020 (CN) 202010105961.4

(51) Int. Cl. A47B 55/00

(52) U.S. Cl. CPC A47B 55/00

(57) ABSTRACT

A structure of reduced profile to render crushproof a cabinet with the structure can be installed in an opening of the cabinet. The structure includes a first frame and a reinforcing portion. Two ends of the reinforcing portion are both connected to the first frame, so that the reinforcing portion is received in the first frame. The crush-proofing structure is movably connected to the opening of the cabinet.

### FIELD

The subject matter herein generally relates to crush-proofing a structure carrying delicate components.

### BACKGROUND

In the era of big data, the seismic requirements of equipment in data centers are becoming more stringent. Cabinets usually need to be equipped with anti-vibration structures to meet seismic requirements. However, the anti-vibration structure is fixed on the cabinet, which will affect the operation of the server in the cabinet.

An improvement is required.

### BRIEF DESCRIPTION OF THE DRAWINGS

Implementations of the present disclosure will now be described, by way of embodiments, with reference to the attached figures.

FIG. 1 is a schematic diagram of an embodiment of an aseismic structure.

FIG. 2 is a schematic diagram of an embodiment of a closed cabinet with the aseismic structure of FIG. 1 installed.

FIG. 3 is a schematic diagram of an embodiment of the cabinet opened with the aseismic structure of FIG. 1 installed.

FIG. 4 is an exploded view of another embodiment of the aseismic structure.

FIG. 5 is a exploded view of the closed cabinet with the aseismic structure of FIG. 4 installed.

FIG. 6 is a exploded view of the opened cabinet with the aseismic structure of FIG. 4 installed.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

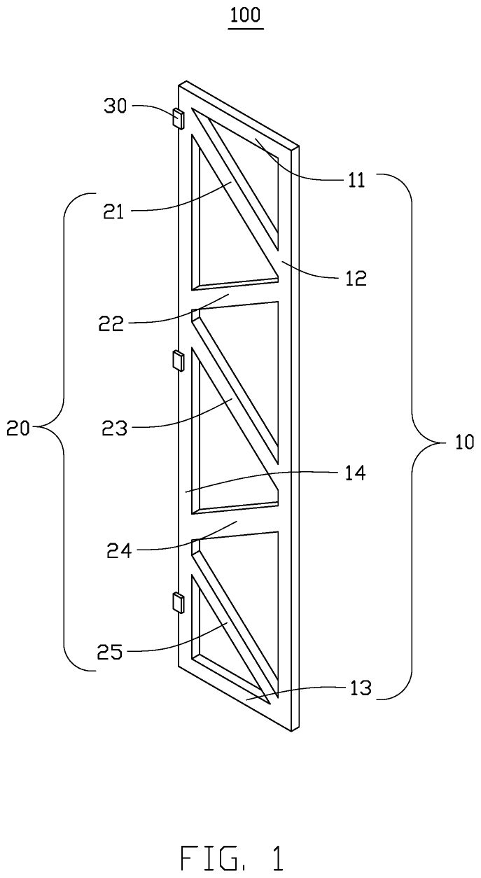

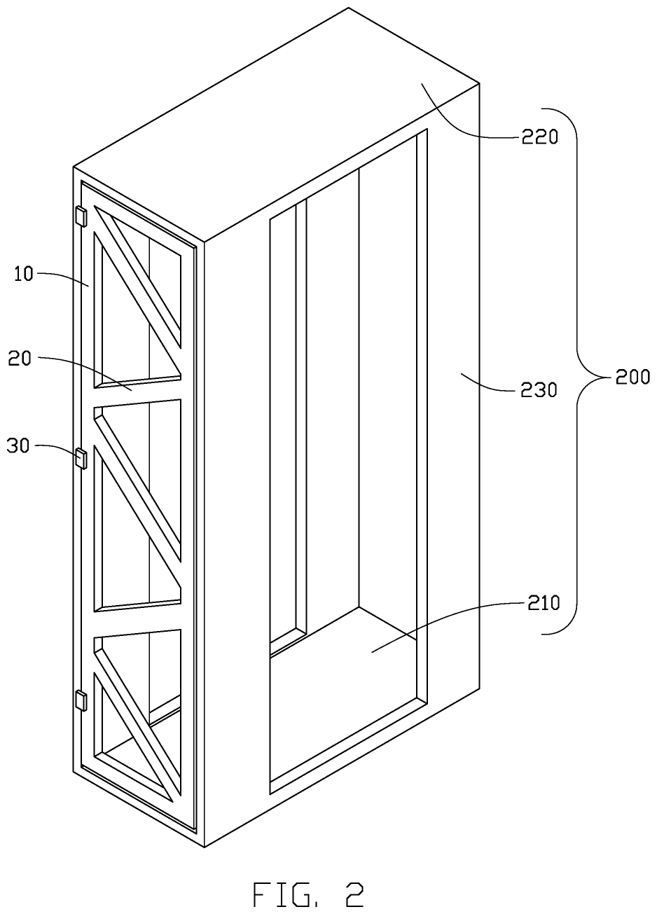

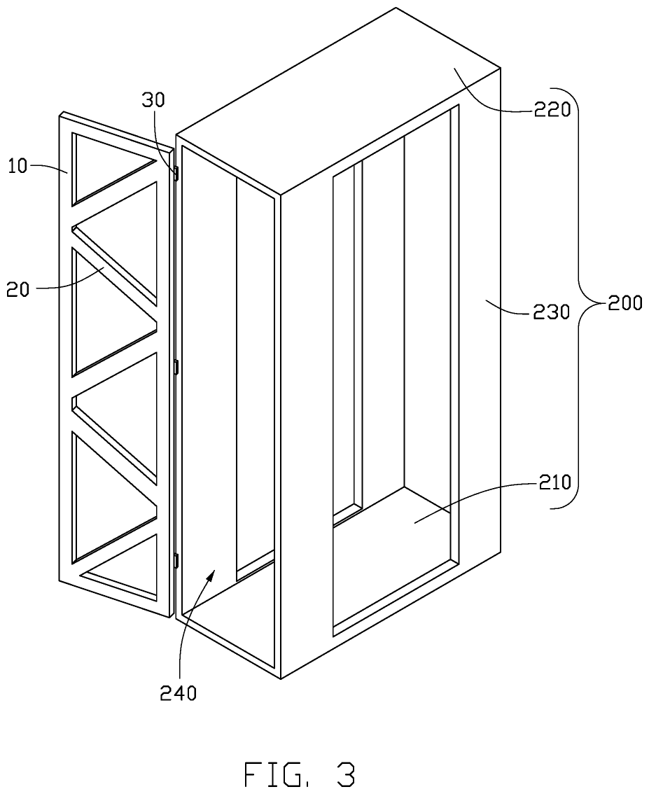

FIG. 1 illustrates an aseismic structure 100 in accordance with an embodiment of the present disclosure. The aseismic structure 100 resists shocks and pressure applied to or experienced by a cabinet 200 (shown in FIG. 2). The cabinet 200 defines an opening 240 (shown in FIG. 3). The aseismic structure 100 is movably connected to the opening 240 of the cabinet 200.

In at least one embodiment, the aseismic structure 100 includes a first frame 10 and a reinforcing portion 20.

Both ends of the reinforcing portion 20 are connected to the first frame 10, and the reinforcing portion 20 is disposed in the first frame 10.

FIGS. 2 and 3 illustrate that the cabinet 200 includes a bottom plate 210 and a top plate 220. A plurality of support plates 230 are disposed between the bottom plate 210 and the top plate 220.

The bottom plate 210, the top plate 220, and the support plates 230 form an accommodation space for placing electronic equipment, such as a server (not shown). The gap between the support plates 230, the bottom plate 210, and the top plate 220 form the opening 240 in the cabinet 200.

In at least one embodiment, the first frame 10 includes a first straight member 11, a second straight member 12, a third straight member 13, and a fourth straight member 14. The first straight member 11, the second straight member 12, the third straight member 13, and the fourth straight member 14 are sequentially connected to form a frame structure. In one embodiment, the frame structure can be a rectangular frame.

In at least one embodiment, the reinforcing portion 20 includes a plurality of reinforcing rods. The reinforcing rods are placed obliquely in the first frame 10, to divide the frame structure formed by the first frame 10 into a plurality of triangles.

In the embodiment, the reinforcing portion 20 includes a first reinforcing rod 21, a second reinforcing rod 22, a third reinforcing rod 23, a fourth reinforcing rod 24, and a fifth reinforcing rod 25. The first reinforcing rod 21, the second reinforcing rod 22, the third reinforcing rod 23, the fourth reinforcing rod 24, and the fifth reinforcing rod 25 are placed obliquely in the first frame 10.

A first end of the first reinforcing rod 21 is connected to a right angle formed by the first straight member 11 and the fourth straight member 14, a second end of the first reinforcing rod 21 is connected to the second straight member 12, and the first reinforcing rod 21 is placed obliquely in the first frame 10.

A first end of the second reinforcing rod 22 and the second end of the first reinforcing rod 21 are connected to the second straight member 12 together, a second end of the second reinforcing rod 22 is connected to the fourth straight member 14, and the second reinforcing rod 22 is placed obliquely in the first frame 10.

A first end of the third reinforcing rod 23 and the second end of the second reinforcing rod 22 are connected to the fourth straight member 14 together, and a second end of the third reinforcing rod 23 is connected to the second straight member 12, and the third reinforcing rod 23 is placed obliquely in the first frame 10.

A first end of the fourth reinforcing rod 24 and the second end of the third reinforcing rod 23 are connected to the second straight member 12 together, a second end of the fourth reinforcing rod 24 is connected to the fourth straight member 14, and the fourth reinforcing rod 24 is placed obliquely in the first frame 10.

A first end of the fifth reinforcing rod 25 and the second end of the fourth reinforcing rod 24 are connected to the fourth straight member 14, and a second end of the fifth reinforcing rod 25 is connected to a right angle formed by the second straight member 12 and the third straight member 13.

The first reinforcing rod 21, the second reinforcing rod 22, the third reinforcing rod 23, the fourth reinforcing rod 24, and the fifth reinforcing rod 25 divide the first frame 10 into a plurality of triangles, the triangles strengthen the pressure bearing capacity of the first frame 10.

In other embodiment, the first frame 10 is not limited to being a rectangular shape, and may be a frame body of other shapes. Specifically, the first frame 10 may be adjusted according to different shapes of the cabinet 200.

In other embodiment, the reinforcing portion 20 is not limited to a reinforcing rod, and may also be a reinforcing member of other shapes or structures, such as a reinforcing sheet. The reinforcing rods of the reinforcing portion 20 are not limited to the above-mentioned installation manner, and may also be other installation methods, such as vertical installation, horizontal installation, or cross installation.

The first frame 10 is movably connected to the opening 240 of the cabinet 200, and the aseismic structure 100 covers the opening 240 of the cabinet 200.

In at least one embodiment, the aseismic structure 100 further includes a connecting member 30, and the connecting member 30 movably connects the first frame 10 to the opening 240 of the cabinet 200.

In the embodiment, one side of the first frame 10 is movably connected to one side of the support plate 230 through the connecting member 30, and the outside of the first frame 10 contacts the inner wall of the opening 240 of the cabinet 200.

The inner wall of the opening 240 can include the inner wall of the bottom plate 210, the inner wall of the top plate 220, and the inner wall of the support plate 230.

In at least one embodiment, the cabinet 200 may be provided with a plurality of the aseismic structures. The cabinet 200 may also be provided with the aseismic structure 100 at different openings.

The reinforcing portion 20 is provided in the first frame 10 to increase the load capacity of the first frame 10.

When the aseismic structure 100 is provided at the opening 240 of the cabinet 200, the aseismic structure 100 effectively increases the pressure bearing capacity of the opening 240 of the cabinet 200, and prevents the support plate 230 from being twisted by the cabinet 200 if knocked over or otherwise crushed, thereby preventing damage to the electronic equipment in the cabinet 200.

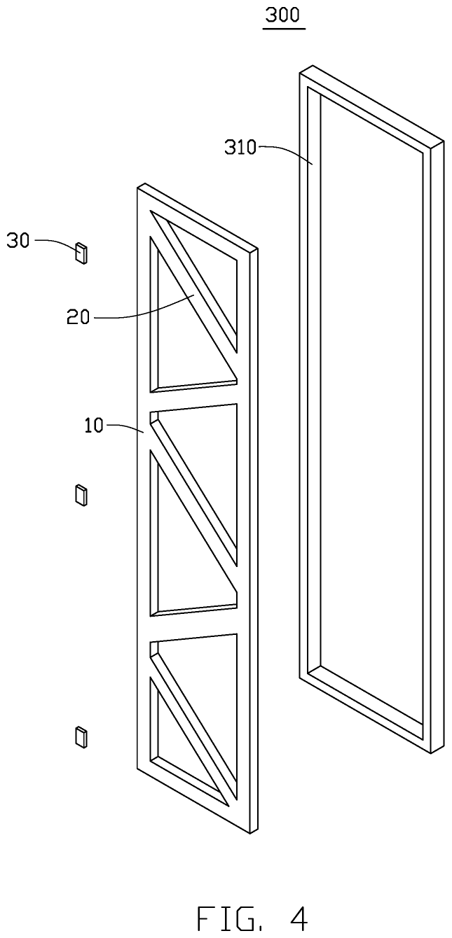

FIG. 4 illustrates an aseismic structure 300 in accordance with another embodiment.

The aseismic structure 300 of the present embodiment differs from the aseismic structure 100 of the first embodiment in that:

In the embodiment, the aseismic structure 300 further includes a second frame 310, and a size of the second frame 310 matches a size of the opening 240 of the cabinet 200.

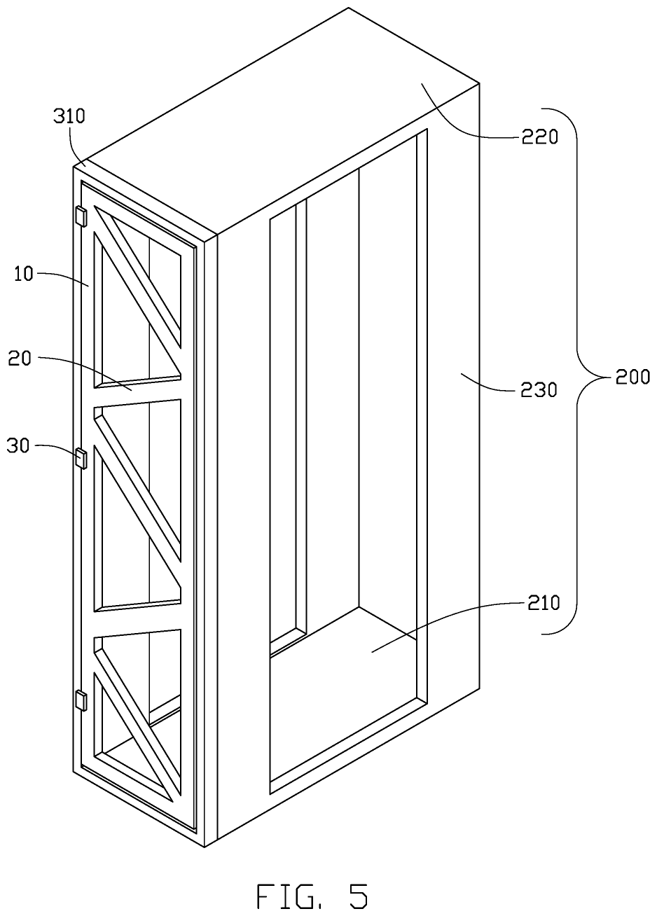

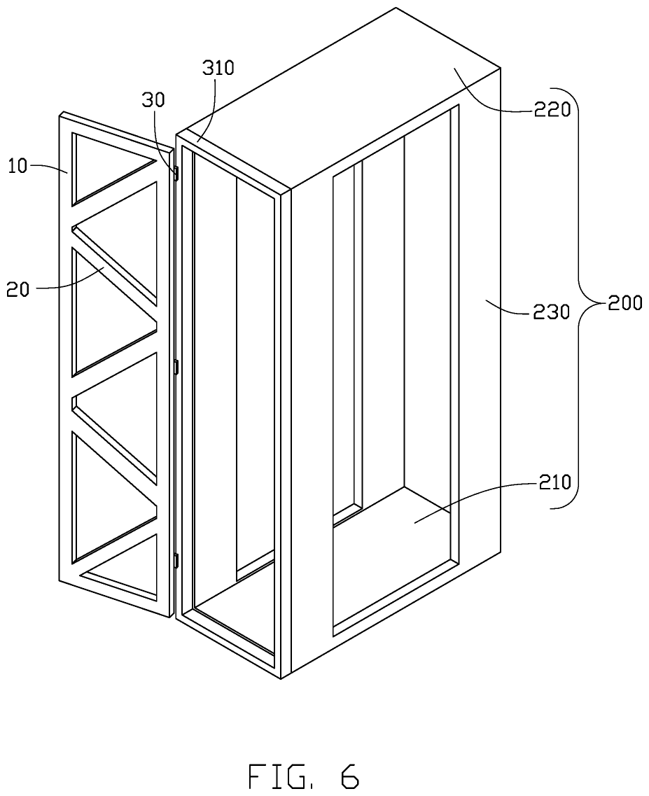

FIGS. 5 and 6 illustrate that the second frame 310 is sleeved on the outer periphery of the first frame 10 and is movably connected to the first frame 10.

When the second frame 310 is completely sleeved on the second frame 310, the outside of the frame of the first frame 10 is in contact with the inside of the frame of the second frame 310. The second frame 310 is further fixedly connected to the opening 240 of the cabinet 200, so that the aseismic structure 300 covers the opening 240 of the cabinet 200.

In the embodiment, the second frame 310 corresponding to the opening 240 is fixedly connected to an outer side wall of the support plate 230. The second frame 310 and the cabinet 200 may be fixedly connected by welding, crimping, or by fasteners.

In the embodiment, the connecting member 30 may be a hinge.

The first frame 10 and the second frame 310 are not limited to being rectangular frames. The shapes of the first frame 10 and the second frame 310 can be adjusted according to the structure of the cabinet 200.

The aseismic structure is provided with the second frame 310, and the aseismic structure 300 can be fixedly installed at the opening 240 of the cabinet 200 when the internal space of the cabinet 200 is limited.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

1. An aseismic structure configured for improving the seismic performance of a cabinet, comprising:
a first frame;
a reinforcing portion disposing in the first frame; wherein both ends of the reinforcing portion are connected to the first frame;
wherein the aseismic structure is movably connected to an opening of the cabinet,
wherein the aseismic structure further comprises a second frame, and the second frame is sleeved on the outer periphery of the first frame, and is movably connected to the first frame; and
wherein when the second frame is completely sleeved on the first frame, outside of the first frame is in contact with inside of the second frame, the second frame is further fixedly connected to the opening of the cabinet, and the aseismic structure covers the opening of the cabinet;
wherein the first frame comprises a first straight member, a second straight member, a third straight member, and a fourth straight member; and wherein the first straight member, the second straight member, the third straight member, and the fourth straight member are sequentially connected to form a frame structure; and
wherein the reinforcing portion comprises a plurality of reinforcing rods, and the reinforcing rods is placed obliquely in the first frame to divide a frame structure formed by the first frame into a plurality of triangles.

2-9. (canceled)

10. The aseismic structure according to claim 1, wherein the reinforcing portion includes a first reinforcing rod, a second reinforcing rod, a third reinforcing rod, a fourth reinforcing rod, and a fifth reinforcing rod; and wherein the first reinforcing rod, the second reinforcing rod, the third reinforcing rod, the fourth reinforcing rod, and the fifth reinforcing rod are placed obliquely in the first frame.

11. A cabinet comprising:
an aseismic structure comprising a first frame and a reinforcing portion; wherein both ends of the reinforcing portion are connected to the first frame
a bottom plate;
a top plate; and a plurality of support plates disposing between the bottom plate and the top plate;
wherein a gap between the support plates, the bottom plate, and the top plate forms a opening in the cabinet, and the aseismic structure is movably connected to the opening of the cabinet
wherein the aseismic structure further comprises a second frame, and the second frame is sleeved on the outer periphery of the first frame, and is movably connected to the first frame; and
wherein when the second frame is completely sleeved on the first frame, outside of the first frame is in contact with inside of the second frame, the second frame is further fixedly connected to the opening of the cabinet, and the aseismic structure covers the opening of the cabinet;
wherein the first frame comprises a first straight member, a second straight member, a third straight member, and a fourth straight member; and wherein the first straight member, the second straight member, the third straight member, and the fourth straight member are sequentially connected to form a frame structure; and
wherein the reinforcing portion comprises a plurality of reinforcing rods, and the reinforcing rods is placed obliquely in the first frame to divide a frame structure formed by the first frame into a plurality of triangles.

12-19. (canceled)

20. The cabinet according to claim 11, wherein the reinforcing portion includes a first reinforcing rod, a second reinforcing rod, a third reinforcing rod, a fourth reinforcing rod, and a fifth reinforcing rod; and wherein the first reinforcing rod, the second reinforcing rod, the third reinforcing rod, the fourth reinforcing rod, and the fifth reinforcing rod are placed obliquely in the first frame.
